(19) United States
(12) Patent Application Publication
(10) Pub. No.: US 2017/0243725 A1
(43) Pub. Date: Aug. 24, 2017

(54) PLASMA PROCESSING APPARATUS

(71) Applicant: TOKYO ELECTRON LIMITED, Tokyo (JP)

(72) Inventors: Ryoji YAMAZAKI, Yamanashi (JP); Susumu SAITO, Yamanashi (JP); Koichi NAGAKURA, Yamanashi (JP); Akitaka SHIMIZU, Yamanashi (JP); Hidetoshi KINOSHITA, Yamanashi (JP)

(21) Appl. No.: 15/435,202

(22) Filed: Feb. 16, 2017

(30) Foreign Application Priority Data
Feb. 19, 2016 (JP) 2016-030387

(51) Int. Cl. H01J 37/32

(52) U.S. Cl. CPC H01J 37/32449; H01J 37/32009; H01J 2237/334

(57) ABSTRACT

In a plasma processing apparatus, insulating members are horizontally and separately arranged above a mounting unit in a processing chamber. Each insulating member serves as a partition between a vacuum atmosphere in the processing chamber and an external atmosphere of the processing chamber. Antennas are provided on the respective insulating members to generate an inductively coupled plasma. A first processing gas is supplied into the processing chamber and adsorbed onto a substrate on the mounting unit. A second processing gas is turned into a plasma by power supplied from the antennas and is supplied to activate the first processing gas adsorbed onto the substrate or react with the first processing gas adsorbed onto the substrate. The supply of the first processing gas and the supply of the second processing gas are alternately repeated multiple times with a process of evacuating an inside of the processing chamber interposed therebetween.

### CROSS-REFERENCE TO RELATED APPLICATIONS

This application claims priority to Japanese Patent. Application No. 2016-030387 filed on Feb. 19, 2016, the entire contents of which are incorporated herein by reference.

### FIELD OF THE INVENTION

The disclosure relates to an apparatus for performing a plasma processing on a substrate in a processing chamber.

### BACKGROUND OF THE INVENTION

In semiconductor device manufacturing process, a plasma processing apparatus for generating an inductively coupled plasma is used as one of apparatuses for performing plasma processing on a single semiconductor wafer (hereinafter, referred to as “wafer”) that is a substrate. In this plasma processing apparatus, a high frequency transmission window made of quartz is provided at a ceiling portion of a processing chamber to partition a vacuum atmosphere and an atmospheric atmosphere and, also, an antenna is provided on the transmission window. By supplying a high frequency power to the antenna, an inductive field is generated in the processing chamber and a processing gas is excited.

Such a plasma processing apparatus may perform an etching process referred to as ALE (Atomic Layer Etching) or a film forming process referred to as ALD (Atomic Layer Deposition) on a substrate. The ALE is a technique of etching a substrate by supplying an adsorptive gas to the substrate, and then supplying active species obtained by exciting a plasma gas to the substrate to activate the gas that has been adsorbed onto the substrate. The ALD is a film forming technique of supplying and adsorbing a raw material gas onto a substrate, exciting a reactant gas, and depositing ti reaction by-product generated by reaction between the excited reactant gas and the raw material gas that has been adsorbed onto the substrate.

Any of the ALD and the ALE includes a step of alternately supplying two different gases multiple times and a step of evacuating an inside of the processing chamber between the supply of one gas and the supply of the other gas. In this connection, the antenna used in the plasma processing apparatus is slightly greater in size than the wafer, and the transmission window has a size corresponding to that of the antenna. Therefore, the processing chamber has a large opening at a top surface thereof where the transmission window is provided, and the transmission window requires a large thickness to ensure pressure resistance.

In order to generate a desired plasma below the transmission window, the power supplied to the antenna needs to be increased. However, if the power is increased, the uniformity of plasma intensity distribution is deteriorated. In order to obtain high uniformity of the plasma on the surface of the wafer, a distance between the transmission window and the wafer needs to be increased. However, if the distance between the transmission window and the wafer is increased, a period of time required to evacuate a space where the wafer is provided is increased. As a consequence, a throughput is decreased.

Japanese Patent Application. Publication No, 2001-3174 discloses an inductively coupled plasma CVD apparatus in which a plurality of high frequency application coils of a hollow structure having a circular cross sectional shape is provided above a reaction chamber having a stage on which a substrate is mounted and the hollow portion is divided into an upper space serving as a heat medium path and a lower space serving as a gas supply path. In this apparatus, the coils are exposed to a processing space. Therefore, if this apparatus is applied to a manufacturing process of semiconductor devices having a miniaturized pattern, a material of the coils or a material of surfaces of the coils may contaminate a film structure of the semiconductor devices.

### SUMMARY OF THE INVENTION

In view of the above, the disclosure provides a technique capable of suppressing a decrease in a throughput by shortening a period of time required for evacuation by reducing a distance between a transmission window of a high frequency electromagnetic field and a substrate in an apparatus for performing plasma processing on a substrate by using the inductively coupled plasma.

In accordance with an embodiment of the present disclosure, there is provided a plasma processing apparatus for performing a plasma processing on a substrate mounted on a mounting unit in a processing chamber of a vacuum atmosphere, the plasma processing apparatus including: a plurality of insulating members provided above the mounting unit to be separated from each other in a horizontal direction, each insulating member serving as a partition between the vacuum atmosphere in the processing chamber and an external atmosphere of the processing chamber; a plurality of antennas provided on the respective insulating members and configured to generate an inductively coupled plasma; a first gas supply unit configured to supply a first processing gas to be adsorbed onto the substrate into the processing chamber; a second gas supply unit configured to supply a second processing gas for activating the first processing gas adsorbed onto the substrate or for processing the substrate by reaction with the first processing gas adsorbed onto the substrate, the second processing gas being turned into a plasma by power supplied from the antennas; and a control unit configured to output a control signal such that the supply of the first processing gas and the supply of the second processing gas are alternately repeated multiple times with a process of evacuating an inside of the processing chamber interposed therebetween.

In the apparatus for performing the plasma processing on the substrate by generating the inductively coupled plasma in the processing chamber of the present disclosure, a plurality of antennas for high frequency generation are arranged in a horizontal direction. The insulating members (transmission windows of the electromagnetic field) provided below the antennas serves the partition between an atmosphere where the antennas are disposed and a vacuum atmosphere in the processing chamber, so that a stress is caused by a pressure difference. Since, however, the insulating member does not have a large size corresponding to that of the substrate but has a small size corresponding to that of each of the antennas, the insulating members each having low pressure resistance may be used. Therefore, the thickness of each of the insulating members can be reduced, and the high frequency power supplied from the antennas can be decreased. Accordingly, the in-plane uniformity of electromagnetic field intensity distribution at a location close to the antennas is increased and the insulating members and the substrate can be positioned close to each other. As a consequence, the space into which the processing gas is supplied can be reduced, and a period of time required for evacuation can be shortened in the case of alternately supplying different processing gases with a step of evacuation interposed therebetween. As a result, a decrease in the throughput can be suppressed.

### BRIEF DESCRIPTION OF THE DRAWINGS

The objects and features of the disclosure will become apparent from the following description of embodiments, given in conjunction with the accompanying drawings, in which:

FIG. 1 is a vertical cross sectional side view showing a plasma processing apparatus according to an embodiment;

FIG. 2 is a perspective view showing a part of the plasma processing apparatus;

FIG. 3 is a top view showing an antenna used in the plasma processing apparatus;

FIG. 4 is a circuit diagram showing a circuit including the antenna used in the plasma processing apparatus;

FIG. 5 explains some dimensions of the plasma processing apparatus;

FIG. 6 is a flowchart showing an operation of the plasma processing apparatus; and

FIGS. 7A and 7B and FIG. 8 schematically explain a part of the operation of the plasma processing apparatus.

### DETAILED DESCRIPTION OF THE EMBODIMENTS

The following is a description of an embodiment in which the present disclosure is applied to a plasma processing apparatus for etching a film on a wafer that is a substrate by alternately supplying an adsorptive gas and a plasma to the wafer.

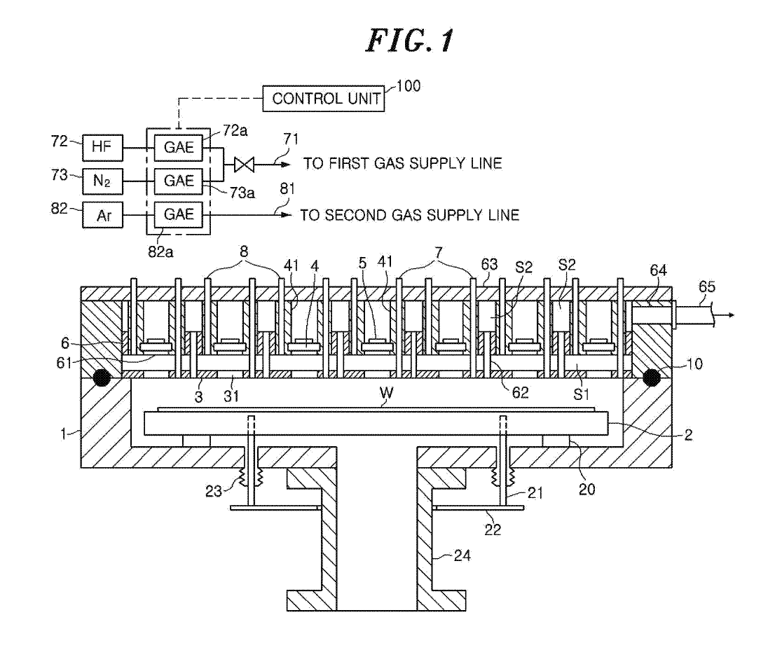

The plasma processing apparatus includes a cylindrical processing chamber 1 made of, e.g., a metal. The processing chamber 1 is maintained under a vacuum atmosphere. A mounting table 2 serving as a mounting unit for mounting thereon a substrate, e.g., a wafer W, is provided on a support 20 at a lower portion in the processing chamber 1. A coolant channel through which a coolant as a temperature control medium (not shown) flows is formed in the mounting table 2. The coolant is supplied from the outside of the processing chamber 1 and discharged to the outside of the processing chamber 1. Accordingly, the mounting table 2 is cooled to a temperature in a range from −10° C. to 10° C., for example. The mounting table 2 is provided with three elevating pins 21 (only two are shown in FIG. 1) for vertically moving the wafer W. The elevating pins 21 can be vertically moved by an elevation member 22 provided under the processing chamber 1. A reference numeral 23 indicates a bellows. A mechanism for vertically moving the elevation member 22 is not illustrated.

A gas exhaust port 24 for vacuum-evacuation is provided at a central portion of a bottom surface of the processing chamber 1. A vacuum pump or a turbo molecular pump serving as an evacuation mechanism is provided at a downstream side of the gas exhaust port 24 via a gas exhaust line (not shown). A gap is formed between the bottom surface of the processing chamber 1 and a bottom surface of the mounting table 2. An atmosphere in the processing chamber 1 is evacuated from the gas exhaust port 24 through the gap. A reference numeral 10 indicates an O-ring that is a seal member.

A buffer plate 3 is provided at an upper portion in the processing chamber 1 to face the mounting table 2, plurality of ventholes 31 is formed in the buffer plate 3 to allow a plasma generated in a space above the buffer plate 3 to flow to a processing space where the wafer W is disposed. The buffer plate 3 is an insulating member made of, e.g., quartz. The buffer plate 3 serves as an ion trapping member for trapping ions in the plasma. Alternatively, the buffer plate 3 may be made of a conductor.

A plurality of quartz plates 4, each of which is a circular plate-shaped insulating member and has a diameter, e.g., in a range from 15 mm to 30 mm, is provided above the buffer plate 3 with a plasma generation space S1 therebetween. Antennas 5 for forming an inductively coupled plasma are provided on the quartz plates 4, respectively. Each of the quartz plates 4 is provided near a lower end of a cylindrical body 41 made of a conductor, e.g., a metal, to cover an opening of the cylindrical body 41. The quartz plate 4 serves as a transmission window for transmitting therethrough a high-frequency electromagnetic field emitted from the antenna 5. As will be described later, the quartz plate 4 further serves as a partition between a vacuum atmosphere in the processing chamber 1 and an external atmospheric atmosphere. The insulating members on which the antennas 5 are provided may be made of, e.g., sapphire.

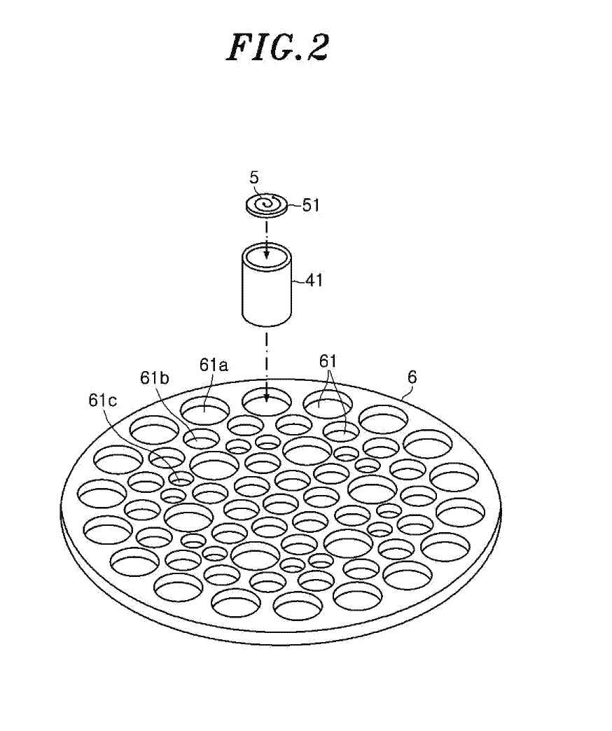

A partition plate 6 having a size corresponding to an inner diameter of the upper portion of the processing chamber 1 is provided at a position corresponding to lower end portions of the cylindrical bodies 41 to face the buffer plate 3. The partition plate 6 includes a plurality of circular openings 61 arranged at intervals as shown in FIG. 2. In this example, the openings 61 include three types of openings 61a to 61c having different diameters. The largest openings 61a and the second largest openings 61b are arranged in concentric circles and the concentric circles of the largest openings 61a and the second largest openings 61b are disposed alternatively from an outermost periphery of the partition plate 6. The smallest openings 61c are formed in areas between the openings 61a and 61b.

The partition plate 6 is preferably made of the same material as that of the cylindrical body 41. Both of the partition plate 6 and the cylindrical body 41 may be made of an insulating material such as quartz or the like. Alternatively, the partition plate 6 and the cylindrical body 41 may be integrally formed by cutting an aluminum material.

The lower end portions of the cylindrical bodies 41 are airtightly fitted in the openings 61, respectively. Therefore, three different sizes (diameters) of the cylindrical bodies 41 corresponding to the three openings 61a to 61c are used.

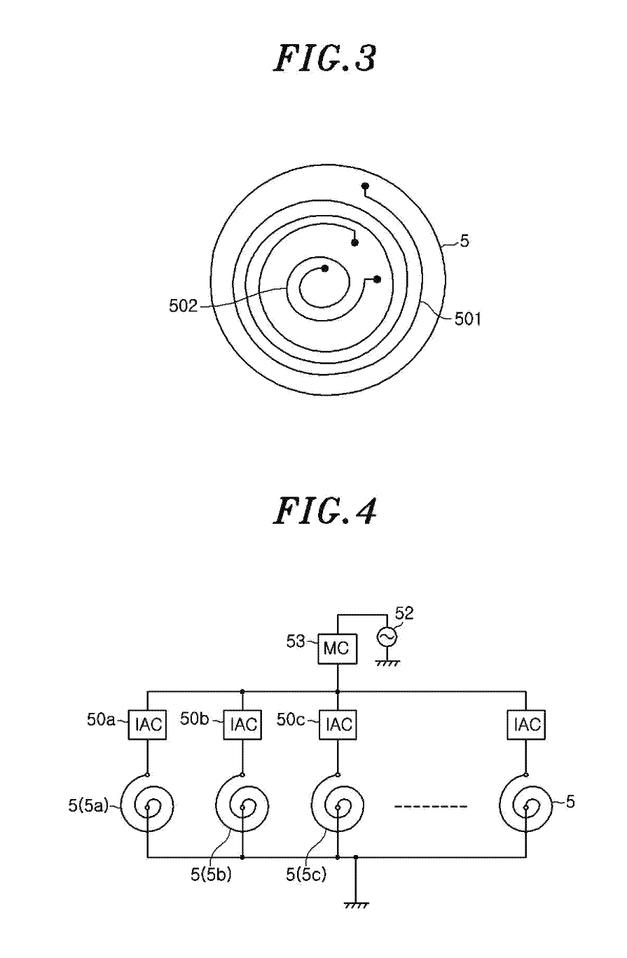

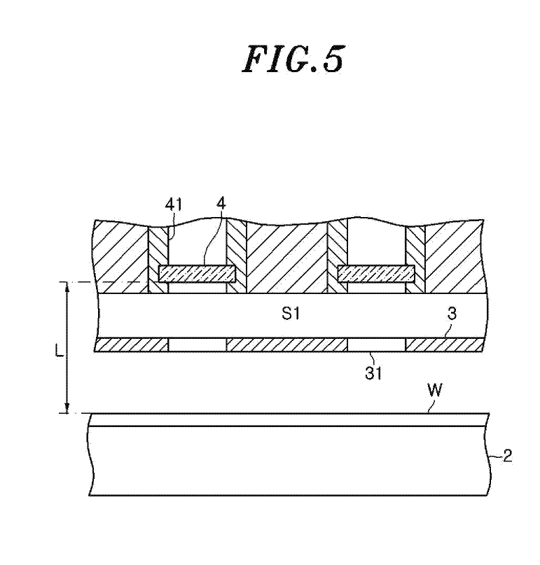

The following is a description of the antenna 5. The antenna 5 is formed in a spiral shape and is attached to a circular circuit board 51 as shown in FIG. 2. Although the circular circuit board 51 is mounted on the quartz plate 4, the illustration of the circuit board 51 is omitted in FIG. 1. As for the antenna 5, there may be used an antenna unit including a first antenna 501 used for a first frequency band in an outer peripheral portion of the circuit board 51 and a second antenna 502 used for a second high frequency band higher than the first frequency band in a central portion of the circuit board 51 as shown in FIG. 3.

Terminals (indicated by black circles) of the first antenna 501 and the second antenna 502 are connected to power feeding cables. The power feeding cables are drawn out to the outside while passing through the cylindrical body 41. The benefit of using such an antenna unit is that there is no need to exchange the antennas since the first and the second antenna 501 and 502 can be switched and selected from a circuit side depending on a frequency band to be used. Further, one of the first and the second antenna 501 and 502 can be used as a plasma ignition and the other can be used as a processing antenna. The plasma can be stably generated by switching the first and the second antenna 501 and 502 properly.

The antennas 5 are indirectly supported by the partition plate 6 and are arranged to cover the entire top surface of the wafer W when seen from the top. As shown in FIG. 4, one ends of the antennas 5 are connected to a common high frequency power supply 52 via a matching circuit (MC) 53 and the other ends of the antennas 5 are grounded. In other words, the antennas are connected in parallel between the high frequency power supply 52 and the ground. To be specific, since the three different sizes (diameters) of the cylindrical bodies 41 are used as described above, three different sizes, i.e., three different planar shapes of the antennas 5 corresponding to those of the cylindrical bodies 41 are used.

In FIG. 4, reference numerals 5a to 5c denote the three antennas 5 in order of size from largest to smallest. The antennas 5 (5a to 5c) have different capacities and, thus, impedance adjusting circuits (IAC) 50a to 50c for adjusting impedances to correspond to the respective antennas 5 are connected in series to the antennas 5a to 5c, respectively. The antennas 5 may be divided into, e.g., a Plurality of groups, each group provided with a high frequency power supply, and the groups are connected in parallel as shown in FIG. 4.

Referring back to the description of the upper portion of the processing chamber 1, a plurality of gas exhaust lines 62 is extended through the partition plate 6 and the buffer plate 3. The upper ends of the gas exhaust lines 62 open to a space above the top surface of the partition plate 6. The lower ends of the gas exhaust lines 62 open to a processing space between the wafer W and the buffer plate 3 while passing through the plasma generation space S1 and the buffer plate 3. The gas exhaust lines 62 are used for locally exhausting an atmosphere of the processing space. The gas exhaust lines 62 are provided over the entire partition plate 6, so that the processing space is exhausted with high uniformity. In the following description, the gas exhaust lines 62 are referred to as local gas exhaust lines 62.

A ceiling plate 63 is provided above the partition plate 6. A space S2 surrounded by the partition plate 6, the ceiling plate 63 and an inner peripheral wall of the upper portion of the processing chamber 1 forms an airtight space. The upper end of each of the local gas exhaust lines 62 opens to the space S2 and, thus, the space S2 serves as a common gas exhaust space for the local gas exhaust lines 62. The ceiling plate 63 is airtightly coupled with upper ends of cylindrical walls of the cylindrical bodies 41. However, detachable covers for covering the respective cylindrical bodies 41 are formed in the ceiling plate 63 at regions corresponding to the uppermost inner spaces of the cylindrical bodies 41. Therefore, the outside of the cylindrical walls of the cylindrical bodies 41 communicates with the processing space and form the airtight space S2 of a vacuum atmosphere, whereas the inside of each cylindrical body 41 communicates with the atmospheric atmosphere.

A gas exhaust port 64 is formed at an upper circumferential wall of the processing chamber 1 to face the gas exhaust space S2. A gas exhaust line 65 is connected to the gas exhaust port 64. The gas exhaust line 65 is joined to a gas exhaust pipe (not shown) connected to the gas exhaust port 24 formed at the bottom portion of the processing chamber 1. Therefore, an atmosphere of the processing space is vacuum-evacuated through the bottom portion of the processing chamber 1 by a common vacuum exhaust unit. At the same time, the atmosphere of the processing space is locally vacuum-evacuated at multiple locations by the local gas exhaust lines 62.

The plasma processing apparatus of the present embodiment includes a plurality of first gas supply lines 7 and a plurality of second gas supply lines 8.

The first gas supply lines 7 penetrate through the partition plate 6 from the ceiling plate 63 via the gas exhaust space S2 and then penetrate through the buffer plate 3 via the plasma generation space S1. The lower ends of the first gas supply lines 7 open to the processing space. The upper ends of the first gas supply lines 7 are connected to a first line 71 of a gas supply system which is simply illustrated at a left upper side of FIG. 1. An upstream side of the first line 71 is branched. An upstream end of one branch line is connected to a gas supply source 72 for supplying a halogen-containing gas, e.g., an HF (hydrogen fluoride) gas that is a halogenated gas. An upstream end of the other branch line is connected to a gas supply source 73 for supplying, e.g., N₂ (nitrogen) gas, as a dilution gas. The HF gas is an adsorptive gas corresponding to a first processing gas. Further, the HF gas adsorbed onto the substrate serves as an etching factor. The first gas supply lines 7 form a part of a first gas supply unit.

The second gas supply lines penetrate through the partition plate 6 from the ceiling plate 63 via the gas exhaust space S2. The lower ends of the second gas supply lines 8 open to the plasma generation space S1. The upper ends of the second gas supply lines 8 are connected to a second line 81. A gas supply source 82 for supplying a plasma gas, e.g., Ar gas, corresponding to a second processing gas for plasma generation is connected to an upstream end of the second line 81. The second gas supply lines 8 form a part of a second gas supply unit. Each of reference numerals 72a, 73 and 82a denotes a group of gas supply equipments (GAE) including valve, flow rate controller and the like.

A plurality of the first gas supply lines 7 and a plurality of the second gas supply lines 8 are arranged such that the gas can be supplied with high uniformity by reducing variation of gas supply over a projection area of the wafer W. In FIG. 2, although portions of the partition plate 6 other than the portions where the openings 61 for the cylindrical bodies 41 are disposed are illustrated to be small for the sake of convenience, it is noted that the arrangement areas of the local gas exhaust lines 62, the first gas supply lines 7 and the second gas supply lines 8 are ensured in the partition plate 6.

In the plasma processing apparatus of the present embodiment, the quartz plates (transmission windows of the electromagnetic field) 4 are distributed and, thus, the distance (height) from the bottom surface of the quartz plates 4 to the top surface of the wafer W can be reduced as will be described later.

As shown in FIG. 1, the plasma processing apparatus of the present embodiment includes a control unit 100 having a computer. The control unit 100 has a program for outputting control signals for a group of the gas supply equipments 72a, 73a and 82a of the gas supply system, the high frequency power supply 52, the pressure control valve provided at the gas exhaust line connected to the gas exhaust port 24 and the like. The program includes a processing recipe in which a sequence of performing plasma processing on the wafer W, processing parameters and the like are recorded. The program is stored in a memory of the control unit 100 by using a storage medium such as a memory disk or the like.

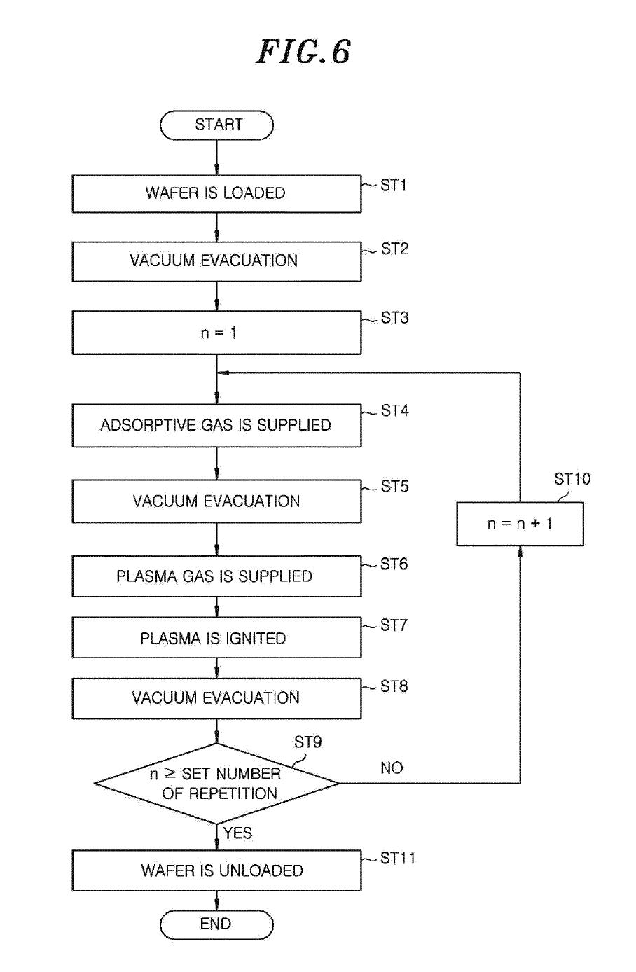

Hereinafter, an operation of the above-described embodiment will be described. A case where a silicon oxide film on a wafer is etched by plasma processing will be described as an example with reference to FIGS. 6 to 8. First, the wafer is loaded into the processing chamber 1 by an external transfer unit. In this loading operation, a gate valve (not shown) is opened and the wafer is loaded into the processing chamber 1 by the transfer unfit. Then, the wafer is transferred to the mounting table by cooperation of the transfer unit and the vertical movement of the elevating pins 21 (step ST1). The mounting table 2 is cooled by the aforementioned coolant and, thus, the wafer is cooled.

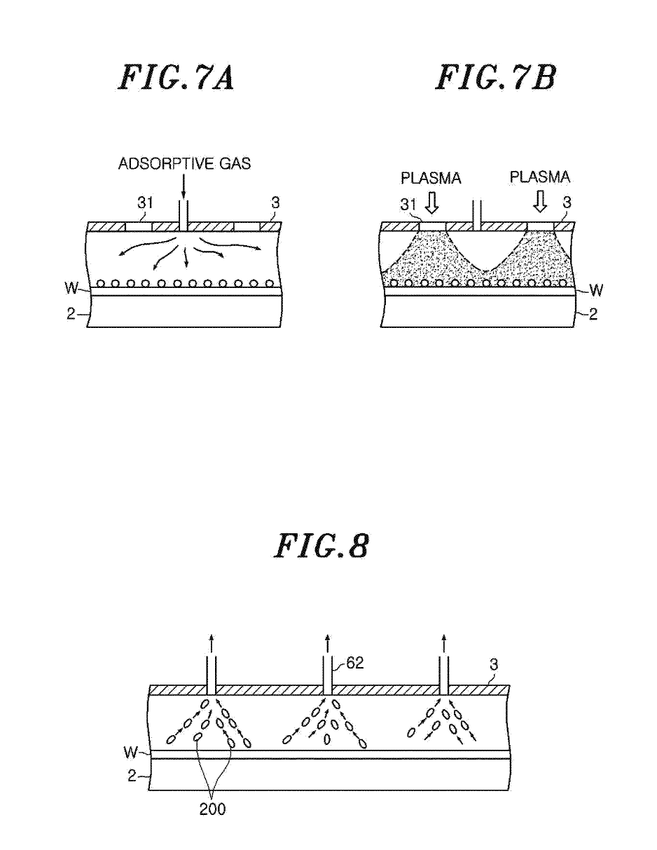

Next, a pressure in the processing chamber 1 is vacuum-evacuated to a level lower than a processing pressure (step ST2). The control unit 100 sets the number of processing cycles ‘n’ in the program to 1 (step ST3). Then, a gaseous mixture of HF gas that is an adsorptive gas (first processing gas) and N₂ gas is supplied from the first gas supply lines 7 to the processing space below the buffer plate 3. Next, as shown in FIG. 7A, the HF gas is adsorbed onto the surface of the wafer W, i.e., the surface of the silicon oxide film in this example (step ST4).

Thereafter, the supply of the adsorptive gas is stopped. An atmosphere of the processing space is exhausted through the local gas exhaust lines 62 above the wafer W and also exhausted through the gas exhaust port 24 formed at the bottom portion of the processing chamber 1 (step ST5).

Subsequently, Ar gas that is a plasma gas (second processing gas) is supplied from the second gas supply lines 8 into the plasma generation space S1 (step ST6), and a high frequency power is supplied from the high frequency power supply 52 to the antennas 5. Thus, a nigh frequency is emitted from the antennas 5 to transmit through the quartz plates 4 and a high-frequency electromagnetic field is generated in the plasma generation space S1. The Ar gas supplied into the plasma generation space S1 is ignited and a plasma is generated (step ST7).

As shown in FIG. 7B, the plasma moves downward to the processing space through the ventholes 31 of the buffer plate 3. Here, ions in the plasma are trapped by the buffer plate 3, so that active species in the plasma of the processing space are mainly Ar radicals. These radicals are brought into contact with HF molecules that have been adsorbed onto the wafer W. Accordingly, the HF molecules are activated and the etching is performed by reaction between the HF molecules and the silicon oxide film. Next, as in the step ST5, an atmosphere of the processing space is exhausted through the local gas exhaust lines 62 and the gas exhaust port 24 (step ST8). At this time, residues (reaction by-products) 200 produced by the etching are discharged as shown in the schematic diagram of FIG. 8. By performing the exhaust through the local gas exhaust lines during the etching of the step ST7, it is possible to prevent the reaction by-products from remaining at the central portion of the wafer W.

Although the vacuum-evacuation is performed during the supply of the adsorptive gas or the supply of the plasma gas, the vacuum-evacuations in the steps ST5 and ST8 are performed at a pressure lower than a pressure at the time of the gas supply.

After one cycle including the adsorption of gas and the etching by activation of adsorbed molecules is completed, the processing returns to the step ST4 via steps ST9 and ST10 to repeat the cycle of the steps ST4 to ST8. When the number of repetition reaches a set number of repetition, the wafer W is unloaded from the processing chamber 1 in the reverse order of the loading operation (step ST11).

In the etching of the silicon oxide film, the adsorptive gas is not limited to HF gas and may be, e.g., NF₃ gas.

In the above embodiment, the configuration in which the plurality of the antennas 5 for high-frequency generation are arranged in a horizontal direction is employed. In other words, the configuration in which the Plurality of the antennas are distributed as a plurality of lower power antennas is employed and, thus, the quartz plate 4 (insulating member) serving as the transmission window of the high-frequency electromagnetic field does not have a large size corresponding to that of the wafer W but has a small size corresponding to that of each of the lower power antennas. Therefore, the quartz plates 4 each having low pressure resistance may be used. Accordingly, the thickness of each of the quartz plates 4 can be reduced and the high frequency power supplied from the antennas 5 can be decreased. As a consequence, the in-plane uniformity of electromagnetic field intensity distribution at a location closed to the antennas 5 is improved and the height of the plasma generation space S1 can be reduced. As a result, the quartz plates 4 and the wafer W can be positioned close to each other. Since the space into which the plasma gas is supplied can be reduced, a period of time required for vacuum-evacuation in the above-described cycle can be shortened and a decrease in a throughput can be suppressed.

The processing chamber 1 is made of a metal. Therefore, when a large power is supplied to an antenna, a distance from the wafer W to the inner wall of the processing chamber 1 needs to be increased in order to suppress unevenness of the plasma distribution and improve uniformity of the plasma distribution near the periphery of the wafer W. In the above embodiment, since the distributed lower power antennas 5 are used, the distance from the wafer W to the inner wall of the processing chamber 1 can be reduced. Therefore, the volume where the gas remains can be reduced, thereby shortening the time for evacuation.

Further, since the configuration in which the small-sized antennas are distributed is employed, it is possible to employ a structure in which a gas can be locally supplied and locally exhausted by using an area where the quartz plates 4 serving as the transmission windows are not provided.

Further, in the above embodiment, three different sizes of the antennas 5 (5a to 5c) are used. Therefore, the wafer in-plane uniformity of the plasma distribution can be improved by arranging large antennas 5 in concentric circles and arranging small antennas 5 in the remaining space. In addition, instead of three different sizes of the antennas, two different sizes of the antennas or four or more different sizes of the antennas may be used.

The antennas 5 are respectively accommodated in the cylindrical bodies 41 made of a metal and, thus, interference between the adjacent antennas 5 can be prevented.

The present disclosure is not limited to the aforementioned structure in which the processing gas is locally supplied by using the plurality of the processing gas supply lines 7 and 8 or the aforementioned structure in which the processing gas is locally exhausted by using the plurality of the gas exhaust lines 62.

Further, the arrangement of the antennas 5 is not limited to the case in which the antennas 5a and 5b are arranged in concentric circles. The antennas 5 may be arranged in a matrix shape or in a zigzag shape.

The present disclosure is not limited to the etching in which the supply of the adsorptive gas and the supply of the plasma are repeated, and may be applied to so-called ALD (Atomic Layer Deposition) in which a film is formed by repeating the supply of an adsorptive gas and the supply of a plasma of a reactant gas. In the case of performing the ALD by using the plasma processing apparatus of the above embodiment, an adsorptive gas, e.g., an organic raw material gas, is supplied from the first gas supply lines 7. Then, ozone gas is supplied from the second gas supply lines 8 and turned into a plasma. Next, a silicon oxide film is formed by oxidizing the organic raw material on the wafer. In this example, the step of supplying an adsorptive gas and the step of supplying a plasma are repeated multiple times, and the step of supplying a substitution gas and the step of vacuum-evacuation are performed between the steps. Therefore, by applying the plasma processing apparatus in accordance with the present disclosure, a period of time required for substituting gases can be shortened.

While the disclosure has been shown and described with respect to the embodiments, it will be understood by those skilled in the art that various changes and modifications may be made without departing from the scope of the disclosure as defined in the following claims.

What is claimed is:

1. A plasma processing apparatus for performing a plasma processing on a substrate mounted on a mounting unit in a processing chamber of a vacuum atmosphere, the plasma processing apparatus comprising:
a plurality of insulating members provided above the mounting unit to be separated from each other in a horizontal direction, each insulating member serving as a partition between the vacuum atmosphere in the processing chamber and an external atmosphere of the processing chamber;
a plurality of antennas provided on the respective insulating members and configured to generate an inductively coupled plasma;
a first gas supply unit configured to supply a first processing gas to be adsorbed onto the substrate into the processing chamber;
a second gas supply unit configured to supply a second processing gas for activating the first processing gas adsorbed onto the substrate or for processing the substrate by reaction with the first processing gas adsorbed onto the substrate, the second processing gas being turned into plasma by power supplied from the antennas; and
a control unit configured to output a control signal such that the supply of the first processing gas and the supply of the second processing gas are alternately repeated multiple times with a process of evacuating an inside of the processing chamber interposed therebetween.

2. The plasma processing apparatus of claim 1, wherein each of the antennas has a spiral shape.

3. The plasma processing apparatus of claim 2, wherein the antennas provided on the respective insulating members include a plurality of types of antennas having different sizes in a plan view.

4. The plasma processing apparatus of claim 1, wherein the second process ing gas is used for etching the substrate by activating the first processing gas adsorbed onto the substrate.

5. The plasma processing apparatus of claim 1, wherein the second processing gas is used for forming a film on the substrate by reaction with the first processing gas adsorbed onto the substrate.

6. The plasma processing apparatus of claim 1, further comprising a buffer plate, which has a plurality of ventholes and is provided between the insulating members and the substrate to face the substrate,
wherein the second gas supply unit includes one or more second gas supply lines, so that the second processing gas supplied through the second gas supply lines is turned into the plasma in a space between the buffer plate and the insulating members and the plasma moves toward the substrate through the ventholes, and
wherein the first gas supply unit includes one or more first gas supply lines for supplying the first processing gas, which are provided separately from the second gas supply lines, and the first gas supply lines open as gas injection holes at a plurality of locations in a bottom surface of the buffer plate.

7. The plasma processing apparatus of claim 1, further comprising a plurality of local gas exhaust lines, for vacuum-evacuating the processing chamber, provided above the substrate mounted on the mounting unit and arranged in the horizontal direction.
